(19) United States
(12) Patent Application Publication
(10) Pub. No.: US 2012/0074549 A1
(43) Pub. Date: Mar. 29, 2012

(54) SEMICONDUCTOR DEVICE WITH EXPOSED PAD

(75) Inventors: Kai Yun YOW, Petaling Jaya (MY); Poh Leng Eu, Petaling Jaya (MY)

(73) Assignee: FREESCALE SEMICONDUCTOR, INC., Austin, TX (US)

(21) Appl. No.: 12/891,820

(22) Filed: Sep. 28, 2010

(51) Int. Cl. H01L 23/495

(52) U.S. Cl. 257/676; 257/E23.031

(57) ABSTRACT

A semiconductor device has a die attached to a die pad and electrically connected to lead fingers. The die, a top surface of the die pad, and a first portion of the lead fingers are covered with a mold compound. A second portion of the lead fingers project from the mold compound and allow for external electrical connection to the die. The mold compound around the die and lead fingers is extended such that a cavity is formed below the die pad. The die pad is exposed via the cavity. A heat sink may be inserted into the cavity and attached to the bottom surface of the die pad.

### BACKGROUND OF THE INVENTION

The present invention relates to semiconductor packaging and more particularly to a semiconductor device with an exposed die pad.

FIG. 1 shows a first conventional Quad Flat Package (QFP) type semiconductor device 10. The QFP device 10 includes an integrated circuit die 12 that is attached to a die pad 14 and electrically connected to lead fingers 16 of a lead frame with wires 18. A mold compound 20 encapsulates the die 12, die pad 14, wires 18 and portions of the leads 16. The QFP device 10 is generally rectangular in shape and the uncovered portions of the leads 16 extend from each of the four sides of the device 10. Variations in QFP designs usually involve differences only in the number of leads, lead pitch, package dimensions, and materials used.

FIG. 2 shows a second conventional QFP type device 22. The QFP device 22 include the IC die 12 attached to the die pad 14 and electrically connected to the lead fingers 16 with the wires 18. However, the second conventional QFP device 22 differs from the first conventional QFP device 10 in that the die pad 14 is exposed. That is, a mold compound 24 covers the die 12, wires 18, portions of the lead fingers 16 and only one of the major surfaces of the die pad 14. The exposed die pad 14 may act as a ground connection and/or as a heat sink for the device 22. For example, when the die pad 14 is soldered to a ground plane of a printed circuit board (PCB), heat generated by the IC die 12 flows from the die 12 to the PCB by way of the die pad 14. The exposed die pad 14 also provides a solid ground connection. However, the die pad 14 also creates an imbalance in stresses on the die, for instance due to different coefficients of thermal expansion (CTE) between the die 12, the die pad 14, the mold compound 24 and the PCB (not shown), which will eventually create a high stress point on the die 12 during a heating cycle of the die 12 and mold compound 24 when the device 22 is being mounted on the PCB.

In view of the foregoing, it would be desirable to have a semiconductor package that experiences decreased CTE stress.

### BRIEF DESCRIPTION OF THE DRAWINGS

The following detailed description of preferred embodiments of the invention will be better understood when read in conjunction with the appended drawings. The present invention is illustrated by way of example and is not limited by the accompanying figures, in which like references indicate similar elements. It is to be understood that the drawings are not to scale and have been simplified for ease of understanding the invention.

FIG. 1 is an enlarged cross-sectional view of a first conventional QFP type semiconductor device;

FIG. 2 is an enlarged cross-sectional view of a second conventional QFP type semiconductor device in which the die pad is exposed;

FIG. 3 is an enlarged cross-sectional view of an exposed pad semiconductor device in accordance with an embodiment of the present invention; and

FIG. 4 is an enlarged cross-sectional view of an exposed pad semiconductor device in accordance with another embodiment of the present invention.

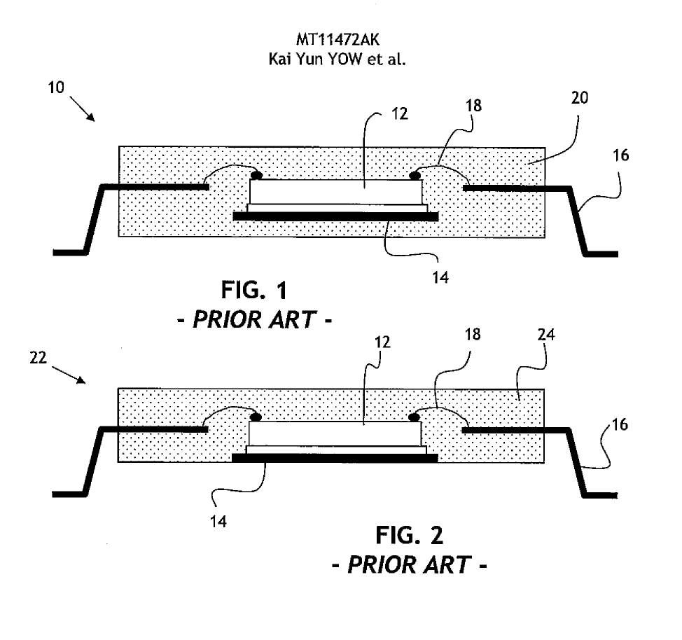

### DETAILED DESCRIPTION OF THE INVENTION

The detailed description set forth below in connection with the appended drawings is intended as a description of the presently preferred embodiments of the invention, and is not intended to represent the only form in which the present invention may be practiced. It is to be understood that the same or equivalent functions may be accomplished by different embodiments that are intended to be encompassed within the spirit and scope of the invention.

In one embodiment, the present invention is a semiconductor device including an integrated circuit (IC) die and a lead frame having a die pad and a plurality of lead fingers disposed on at least two opposing sides of the die pad. The IC die is attached to a top surface of the die pad and is electrically connected to the plurality of lead fingers. A mold compound covers the IC die, a top surface of the die pad, and a first portion of the lead fingers. A second portion of the lead fingers is exposed on two opposing sides of the semiconductor device. The exposed portions allow for external electrical connection to the IC die. The mold compound includes a cavity below the die pad such that a bottom surface of the die pad is exposed. The cavity may have a depth of about 0.2-0.5 mm for a package of 1.2 mm thickness. In a further embodiment, a heat sink is located within the cavity.

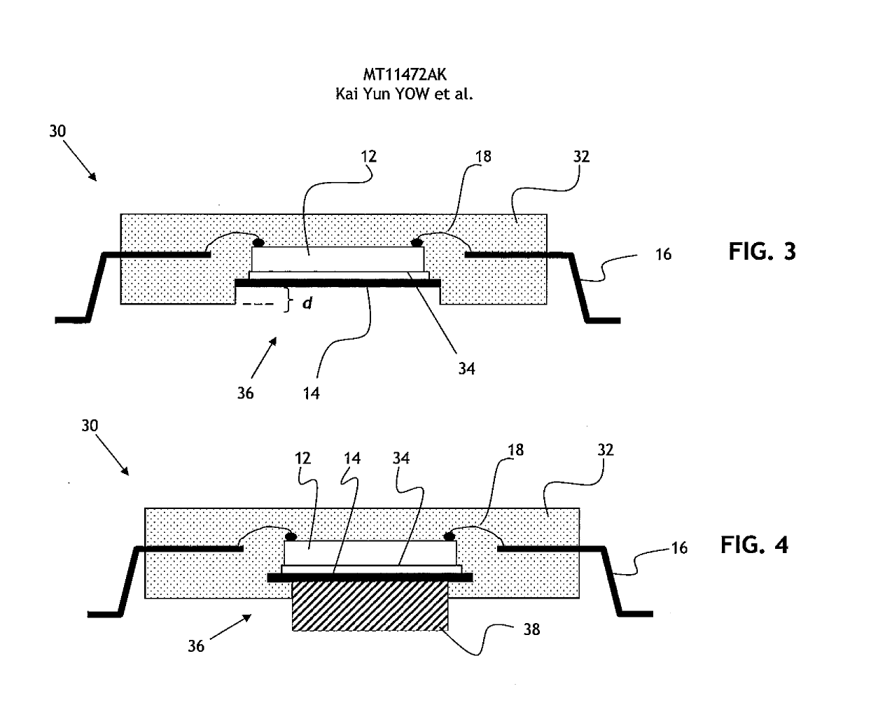

Referring now to FIG. 3, an enlarged cross-sectional view of a semiconductor device 30 is shown. The semiconductor device 30 includes an integrated circuit (IC) die 12 and a lead frame having a flag or die pad 14 and a plurality of lead fingers 16 disposed on at least two opposing sides of the die pad 14. The IC die 12 may be a processor, such as a digital signal processor (DSP), a special function circuit, such as a memory address generator, or a circuit that performs any other type of function. The IC die 12 is not limited to a particular technology such as CMOS, or derived from any particular wafer technology. Further, the present invention can accommodate various die sizes, as will be understood by those of skill in the art. A typical example is a memory die having a size of about 15 mm².

The IC die 12 is attached to a top surface of the die pad 14 with an epoxy 34 or other substance, such as an adhesive (glue) or even an adhesive tape so long as the adhesive is able to withstand the high temperatures it would be subjected to during the semiconductor packaging process. The die 12 also is electrically connected to the plurality of lead fingers 16 with wires 18, as shown in FIG. 3. The bonding wires 18 may be made of gold (Au), copper (Cu), aluminium (Al) or other electrically conductive materials as are known in the art and commercially available. However, as also will be understood by those of skill in the art, the die 12 may be electrically connected to the lead fingers 16 using bumps or balls as is common with flip-chip technology.

A mold compound 32 covers the IC die 12, a top surface of the die pad 14 (or at least those portions of the top and sides of the die pad 14 that are not covered by the die 12 and the epoxy 34), and a first portion of the lead fingers 16. The first, encapsulated portions of the lead fingers 16 may lie in a separate plane than the die pad 34, as shown in FIG. 3, or the first portions of the lead fingers 34 may lie in the same plane as the die pad 34. A second portion of the lead fingers 16 is exposed on the at least two opposing sides of the semiconductor device 30. The exposed second portions allow for external electrical connection to the IC die 12, for example, by attaching the device 30 to a printed circuit board. The exposed second portions may project or extend outwardly from the mold compound 32 as is shown in FIG. 3 (QFP type package) or the lead fingers 16 could be bent into alternate configurations, or be cut flush with an outer surface of the mold compound (QFN type package), as is known by those of skill in the art. The semiconductor device 30 therefore may be any type of wire-bonded package or bump bonded package such as, for example, BGA, QFN, QFP, PLCC, CUEBGA, TBGA, and TSOP.

The molding compound 32 extends beyond a plane of the die pad 14 and includes a cavity 36 located below the die pad 14 such that a bottom surface of the die pad 14 is exposed. The cavity 36 is formed during the molding or encapsulation process using a mold chase that is designed to form the cavity. A molding operation such as, for example, an injection molding process may be used to perform the encapsulation. The molding compound 32 may comprise well-known commercially available molding materials such as plastic or epoxy. In a preferred embodiment of the invention the cavity 36 has a depth d of about 0.2 to 0.5 mm for a package that has an overall thickness of about 1.2 mm. Of course, for packages of different thickness, the cavity depth d may vary. The extended portion of the mold compound 32 strengthens the package from warpage due to thermal stress and CTE mismatch between the die 12, die pad 14 and mold compound 32.

Referring now to FIG. 4, another embodiment of the semiconductor device 30 is shown. In this embodiment, the device 30 includes a heat sink 38 attached to an underside of the die pad 14. The heat sink 38 should be made of a material that has good heat transfer properties, such as copper. The heat sink 38 preferably is installed within the cavity and attached to the die pad 14 using solder so that there is a good metal-to-metal interface. However, in an alternative embodiment, the heat sink 38 could be installed within the cavity 36 an epoxy adhesive such as one that is similar to the one used for attaching the die 12 to the die pad 14. In one embodiment, the heat sink 38 is sized and shaped to fit snugly within the cavity 26, while in an alternate embodiment, the heat sink 30 extends beyond the cavity 36 and is not flush with the molding compound 32 on the underside of the semiconductor device 30 (as shown in FIG. 4). In this embodiment, the cavity 36 strengthens the package so that it is not damaged when the heat sink 38 is installed within the cavity. The cavity 36 may also be used to limit the size of the heat sink 38 that can be attached to the IC die 12. For example, if the length of the cavity 26 is less than a length of the IC die 12, then the heat sink must have a width that is less than a length of the die 12. FIG. 4 shows this example. The heat sink 38 is shown in FIG. 4 as a slug or rectangle. However, as will be understood by those of skill in the art, the heat sink may take on different shapes. For example, a circular heat spreader or a heat spreader having a T-shaped cross-section could be used.

As is evident from the foregoing discussion, the present invention provides a method of forming a stable semiconductor device. While the preferred embodiments of the invention have been illustrated and described, it will be clear that the invention is not limited to these embodiments only. Numerous modifications, changes, variations, substitutions and equivalents will be apparent to those skilled in the art without departing from the spirit and scope of the invention as described in the claims.

1. A semiconductor device, comprising:
an integrated circuit (IC) die;
a lead frame having a die pad and a plurality of lead fingers disposed on at least two opposing sides of the die pad, wherein the IC die is attached to a top surface of the die pad and is electrically connected to the plurality of lead fingers; and
a mold compound covering the IC die, a top surface of the die pad, and a first portion of the lead fingers, wherein a second portion of the lead fingers is exposed on two opposing sides of the semiconductor device, said exposed portions allowing for external electrical connection to the IC die; and
wherein the mold compound includes a cavity below the die pad such that a bottom surface of the die pad is exposed.

2. The semiconductor device of claim 1, wherein the cavity has a depth of about 0.2 to 0.5 mm.

3. The semiconductor device of claim 2, wherein the lead frame includes lead fingers disposed on four sides of the die pad and wherein the lead fingers are exposed on respective four sides of the semiconductor device.

4. The semiconductor device of claim 2, wherein the IC die is attached to the die pad with epoxy.

5. The semiconductor device of claim 2, wherein the IC die is electrically connected to the lead fingers with wires.

6. The semiconductor device of claim 2, wherein the second, exposed portions of the lead fingers are flush with an outer surface of the mold compound.

7. The semiconductor device of claim 2, wherein the second, exposed portions of the lead fingers project outwardly from the outer surface of the mold compound.

8. The semiconductor device of claim 7, wherein the first portions of the lead fingers lie in a same plane as the die pad.

9. The semiconductor device of claim 7, wherein the second, exposed portions of the lead fingers are bent.

10. A semiconductor device, comprising:
an integrated circuit (IC) die;
a lead frame having a die pad and a plurality of lead fingers disposed on at least two opposing sides of the die pad, wherein the IC die is attached to a top surface of the die pad and is electrically connected to the plurality of lead fingers; and
a mold compound covering the IC die, a top surface of the die pad, and a first portion of the lead fingers, wherein a second portion of the lead fingers is exposed on two opposing sides of the semiconductor device, said exposed portions allowing for external electrical connection to the IC die; and
wherein the mold compound includes a cavity below the die pad such that a bottom surface of the die pad is exposed, wherein the cavity has a depth of about 0.2 to 0.5 mM.

11. The semiconductor device of claim 10, wherein the device is a Quad Flat No Lead (QFN) type package.

12. The semiconductor device of claim 10, wherein the device is a Quad Flat Package (QFP) type package.
